(19) United States
(12) Patent Application Publication
(10) Pub. No.: US 2024/0059024 A1
(43) Pub. Date: Feb. 22, 2024

(54) APPARATUS AND METHOD FOR IDENTIFYING CRITICAL FEATURES USING MACHINE LEARNING

(71) Applicant: Markforged, Inc., Waltham, MA (US)

(72) Inventors: Bruce David Jones, Sudbury, MA (US); David Steven Benhaim, Miami, FL (US)

(21) Appl. No.: 18/450,641

(22) Filed: Aug. 16, 2023

Related U.S. Application Data
(60) Provisional application No. 63/399,008, filed on Aug. 18, 2022.

(51) Int. Cl. B29C 64/393; B29C 64/118; B29C 64/188; B33Y 40/20; B33Y 50/02

(52) U.S. Cl. CPC B29C 64/393; B29C 64/118; B29C 64/188; B33Y 40/20; B33Y 50/02; B33Y 10/00

(57) ABSTRACT

A 3D printing apparatus and method determines features based on design data of an object and at least one classification of a determined feature. The at least one classification includes a classification that the determined feature is a critical feature for the object. At least one print setting for forming the determined feature is modified based on the classification that the determined feature is a critical feature.

This application claims priority to U.S. Provisional Application No. 63/399,008, filed Aug. 18, 2022, which is incorporated by reference herein in its entirety.

### FIELD OF THE INVENTION

The invention relates to an apparatus and method for identifying critical features in a 3D printing apparatus using machine learning.

### BACKGROUND OF THE INVENTION

When producing a part using 3D printing, certain portions of the part may often be more significant than others. For example, certain portions may provide structural support or rigidity and/or may operate as coupling areas that couple with other components. These portions may benefit from special attention, such as in the form of reduced tolerances for geometric deviations, a different print technique that benefits the criticality (e.g., print technique that strengthens rigidity in a critical area), etc.

Therefore, a need exists to automatically detect and classify features in users' 3D part geometry, including classifying certain features as critical features (or any other useful metadata/labels)

A need also exists to collect user input/interaction to further train one or more machine learning models.

### SUMMARY OF THE INVENTION

One aspect of the present invention relates to an apparatus comprising at least one processor; and at least one memory, wherein the at least one memory stores computer-readable instructions which, when executed by the at least one processor, cause the processor to: receive design data corresponding to an object; determine, based on the design data, features of the object; determine, of the determined features, at least one classification for at least one determined feature; and generate production data based on the design data, the determined features, and the determined at least one classification.

Another aspect of the present invention relates to an apparatus comprising: at least one processor; and at least one memory, wherein the at least one memory stores computer-readable instructions which, when executed by the at least one processor, cause the processor to: generate a machine learning model configured to recognize features in a design of an object; receive design data corresponding to an object; execute the machine learning model on the design, to output recognized features in the design; present the recognized features to a user; receive feedback relating to the recognized features; and update the machine learning model, based on the feedback relating to the recognized features.

Yet another aspect of the present invention relates a method comprising: receiving design data corresponding to an object; determining, based on the design data, features of the object; determining, of the determined features, at least one classification for at least one determined feature; and generating production data based on the design data, the determined features, and the determined at least one classification.

Still another aspect of the present invention relates to a method comprising: generating a machine learning model configured to recognize features in a design of an object; receiving design data corresponding to an object; executing the machine learning model on the design, to output recognized features in the design; presenting the recognized features to a user; receiving feedback relating to the recognized features; and updating the machine learning model, based on the feedback relating to the recognized features.

These and other aspects of the invention will become apparent from the following disclosure.

### BRIEF DESCRIPTION OF THE DRAWINGS

FIGS. 1A and 1B illustrate an apparatus, in accordance with one embodiment, and FIG. 1C illustrates a system, in accordance with one embodiment.

FIG. 2 is a block diagram illustrating a feature analysis component of the system, in accordance with one embodiment.

FIG. 3 is a flow chart illustrating a general methodology for identifying and classifying features, in accordance with one embodiment.

FIG. 4 is a flow chart for training feature detection and feature classification machine learning models, in accordance with one embodiment.

FIG. 5 is a flow chart for training feature detection and feature classification machine learning models using a semantic segmentation approach, in accordance with one embodiment.

FIG. 6 is a flow chart for training feature detection and feature classification machine learning models using a forced projection approach, in accordance with one embodiment.

FIG. 7 is a flow chart for training feature detection and feature classification machine learning models using a voxelization approach, in accordance with one embodiment.

FIG. 8 is a flow chart for presenting critical features to a user, in accordance with one embodiment.

FIG. 9 is a flow chart for in-process detection of print accuracy of critical features, in accordance with one embodiment.

FIG. 10 is a flow chart for post-process detection of print accuracy of critical features, in accordance with one embodiment.

FIG. 11 is a flow chart for compensating for critical features, in accordance with one embodiment.

### DETAILED DESCRIPTION OF THE PREFERRED EMBODIMENTS

The present invention relates to an apparatus and method of detecting and classify features in user part geometry and classifying certain features as critical features (or any other useful label/classification/metadata). The present invention relates to utilizing machine learning to perform the detection and/or classification operations.

In one aspect of the invention, user input may be used to further train one or more machine learning models. In one aspect, user input is used to train at least two machine learning models, such as at least one machine learning model for feature detection and at least one machine learning model for feature classification.

It will be appreciated that benefits derived from the present invention may include improvement of user engagement and improvement of print outcomes, while accommodating security-conscious users by isolating the users' data so that such data is only used to train models specific to those users' work product.

3D Printer Apparatus

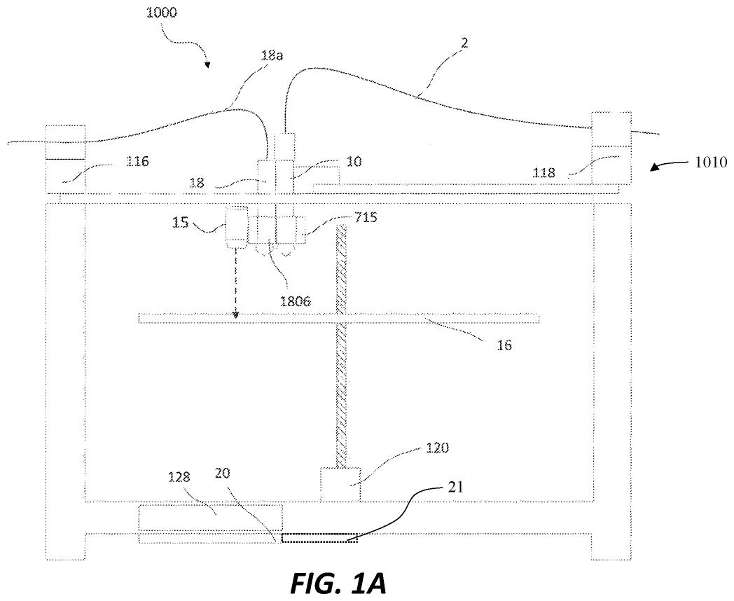

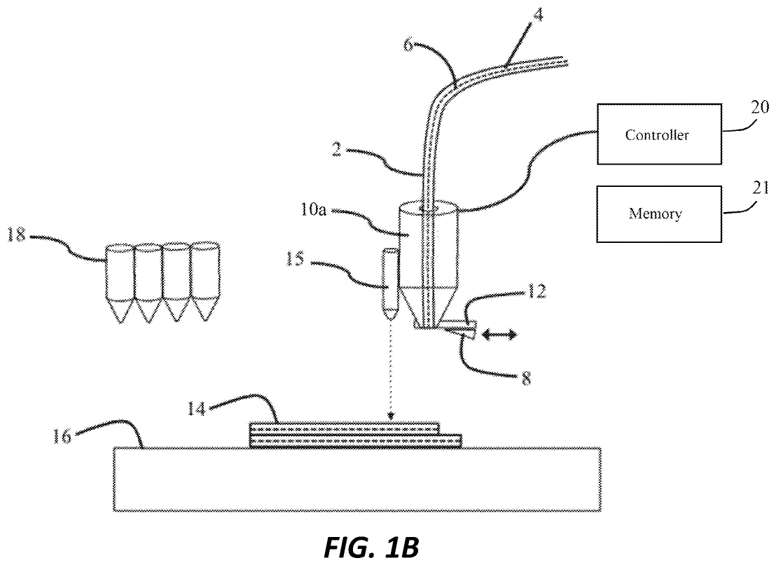

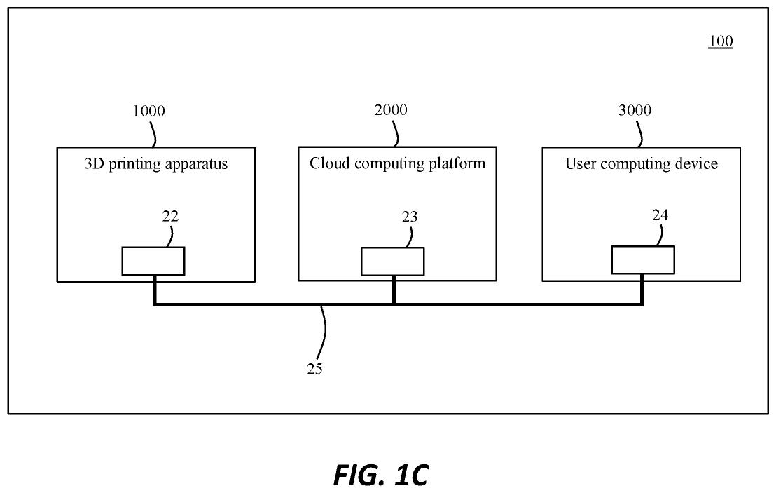

FIGS. 1A-1B illustrate an apparatus 1000 in accordance with one embodiment of the invention. The apparatus 1000 includes one or more controllers 20, one or more memories 21, and one or more print heads 10, 18. For instance, one head 10 may deposit a metal or fiber reinforced composite filament 2, and another head 18 may apply pure or neat matrix resin 18a (thermoplastic or curing), which may include, but is not limited to, a polymer or curable monomer and/or a polymer or curable monomer filled, e.g., with chopped carbon fiber, carbon black, silica, and/or aramid fiber. In the case of the filament 2 being a fiber reinforced composite filament, such filament (also referred to herein as continuous core reinforced filament) may be substantially void free and include a polymer or resin that coats, permeates or impregnates an internal continuous core (including, but not limited to, single, multi-strand, or multi-material). It should be noted that although the print head 18 is shown as an extrusion print head, “fill material print head” 18 as used herein includes optical or UV curing, heat fusion or sintering, or “polyjet”, liquid, colloid, suspension or powder jetting devices (not shown) for depositing fill material. It will also be appreciated that a material bead formed by the filament 2 may be deposited as extruded thermoplastic or metal, deposited as continuous or semi-continuous fiber, solidified as photo or UV cured resin, or jetted as metal or binders mixed with plastics or metal, or are structural, functional or coatings. The fiber reinforced composite filament 2 (also referred to herein as continuous core reinforced filament) may be a push-pulpreg that is substantially void free and includes a polymer or resin 4 that coats or impregnates an internal continuous single core or multistrand core 6. The apparatus includes heaters 715, 1806 to heat the print heads 10, 18, respectively so as to facilitate deposition of layers of material to form the object 14 to be printed. A cutter 8 controlled by the controller 20 may cut the filament 2 during the deposition process in order to (i) form separate features and components on the structure as well as (ii) control the directionality or anisotropy of the deposited material and/or bonded ranks in multiple sections and layers. As depicted, the cutter 8 is a cutting blade associated with a backing plate 12 located at the nozzlet outlet. Other cutters include laser, high-pressure air or fluid, or shears. The apparatus 1000 may also include additional non-printing tool heads, such as for milling, SLS, etc.

The apparatus 1000 includes a gantry 1010 that supports the print heads 10, 18. The gantry 1010 includes motors 116, 118 to move the print heads 10, 18 along X and Y rails in the X and Y directions, respectively. The apparatus 1000 also includes a build platen 16 (e.g., print bed) on which an object to be printed is formed. The height of the build platen 16 is controlled by a motor 120 for Z direction adjustment. Although the movement of the apparatus has been described based on a Cartesian arrangement for relatively moving the print heads in three orthogonal translation directions, other arrangements are considered within the scope of, and expressly described by, a drive system or drive or motorized drive that may relatively move a print head and a build plate supporting a 3D printed object in at least three degrees of freedom (i.e., in four or more degrees of freedom as well). For example, for three degrees of freedom, a delta, parallel robot structure may use three parallelogram arms connected to universal joints at the base, optionally to maintain an orientation of the print head (e.g., three motorized degrees of freedom among the print head and build plate) or to change the orientation of the print head (e.g., four or higher degrees of freedom among the print head and build plate). As another example, the print head may be mounted on a robotic arm having three, four, five, six, or higher degrees of freedom; and/or the build platform may rotate, translate in three dimensions, or be spun.

FIG. 1B depicts an embodiment of the apparatus 1000 applying the filament 2 to build a structure. In one embodiment, the filament 2 is a metal filament for printing a metal object. In one embodiment, the filament 2 is a fiber reinforced composite filament (also referred to herein as continuous core reinforced filament) may be a push-pulpreg that is substantially void free and includes a polymer or resin 4 that coats or impregnates an internal continuous single core or multistrand core 6.

The filament 2 is fed through a nozzlet 10a disposed at the end of the print head 10, and heated to extrude the filament material for printing. In the case that the filament 2 is a fiber reinforced composite filament, the filament 2 is heated to a controlled push-pultrusion temperature selected for the matrix material to maintain a predetermined viscosity, and/or a predetermined amount force of adhesion of bonded ranks, and/or a surface finish. The push-pultrusion may be greater than the melting temperature of the polymer 4, less than a decomposition temperature of the polymer 4 and less than either the melting or decomposition temperature of the core 6.

After being heated in the nozzlet 10a and having its material substantially melted, the filament 2 is applied onto the build platen 16 to build successive layers 14 to form a three dimensional structure. One or both of (i) the position and orientation of the build platen 16 or (ii) the position and orientation of the nozzlet 10a are controlled by a controller 20 to deposit the filament 2 in the desired location and direction. Position and orientation control mechanisms include gantry systems, robotic arms, and/or H frames, any of these equipped with position and/or displacement sensors to the controller 20 to monitor the relative position or velocity of nozzlet 10a relative to the build platen 16 and/or the layers 14 of the object being constructed. The controller 20 may use sensed X, Y, and/or Z positions and/or displacement or velocity vectors to control subsequent movements of the nozzlet 10a or platen 16. The apparatus 1000 may optionally include a laser scanner 15 to measure distance to the platen 16 or the layer 14, displacement transducers in any of three translation and/or three rotation axes, distance integrators, and/or accelerometers detecting a position or movement of the nozzlet 10a to the build platen 16. The laser scanner 15 may scan the section ahead of the nozzlet 10a in order to correct the Z height of the nozzlet 10a, or the fill volume required, to match a desired deposition profile. This measurement may also be used to fill in voids detected in the object. The laser scanner 15 may also measure the object after the filament is applied to confirm the depth and position of the deposited bonded ranks. Distance from a lip of the deposition head to the previous layer or build platen, or the height of a bonded rank may be confirmed using an appropriate sensor.

Various 3D-printing aspects of the apparatus 1000 are described in detail in U.S. Patent Application Publication No. 2019/0009472, which is incorporated by reference herein in its entirety.

System

FIG. 1C illustrates a system 100 in accordance with one embodiment of the invention. The system 100 includes the 3D printing apparatus 1000, a cloud computing platform 2000, and a user computing device 3000.

Each system component may communicate with the remaining components through a respective network interface and a network 25 (such as a local area network or the Internet). For example, the 3D printing apparatus 1000 may include, in addition to the aforementioned features, a network interface 22 for connecting the apparatus 1000 to the network 25.

The cloud computing platform 2000 may likewise include a network interface 23 for connecting the cloud computing platform 2000 to the network 25. Further aspects of the cloud computing platform 2000 will be described below.

The user computing device 3000 may similarly include a network interface 24 for connecting the user computing device 3000 to the network 25. The user computing device 3000 may include, but is not limited to, a personal computer such as a desktop or laptop, a thin client, a tablet, cellular phone, interactive display, or any other device with a user interface and configured to communicate with one or both of the 3D printing apparatus 1000 and the cloud computing platform 2000.

It will be appreciated that the network 25 is illustrated in FIG. 1C as a single network connecting the system components, the network 25 may actually be composed of a combination of multiple networks (e.g., both a local area network and the Internet). It will also be appreciated that a system component may communicate with only one of the remaining system components rather than both. For example, each of the 3D printing apparatus 1000 and the user computing device 3000 may communicate with the cloud computing platform 2000 but may not communicate with each other.

Computing Platform

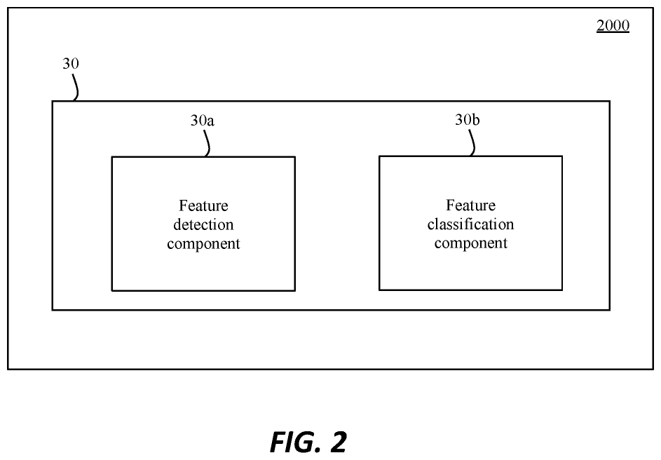

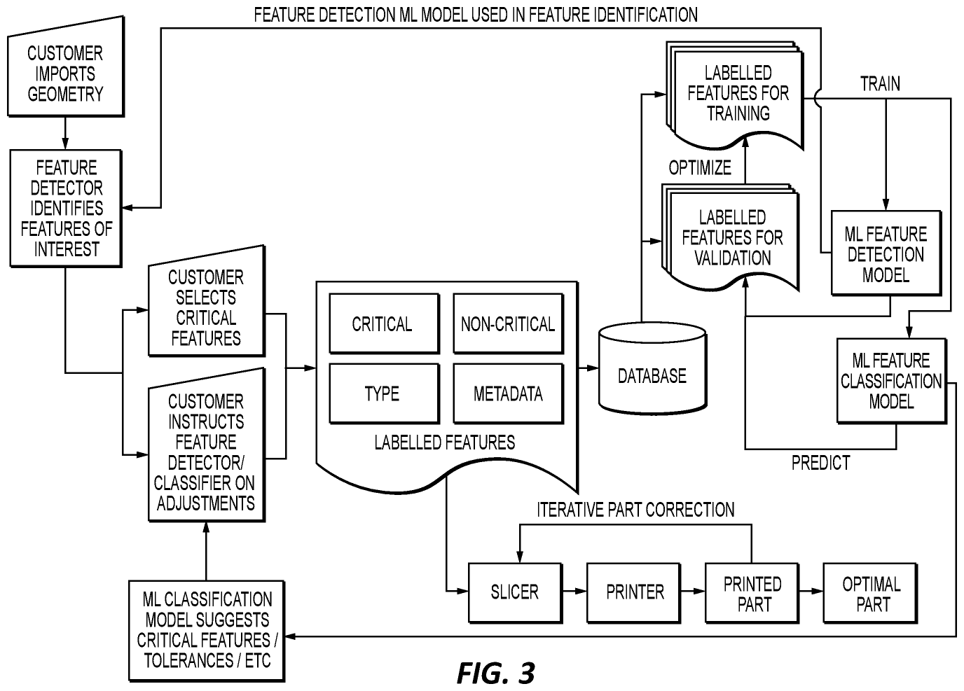

FIG. 2 illustrates features of the cloud computing platform 2000, in accordance with one embodiment of the invention, and FIG. 3 illustrates a general methodology for identifying and classifying features. In one embodiment, the cloud computing platform 2000 includes a feature analysis component 30 for analyzing features of a 3D part design. In one aspect of the invention, the feature analysis component 30 may include a feature detection component 30a and a feature classification component 30b.

In one aspect of the invention, the feature detection component 30a detects features within 3D part geometry. In one embodiment, the feature detection component 30a may be implemented using one or more geometric feature detection algorithms. In one embodiment, the feature detection component 30a may be implemented using one or more machine learning-based feature detection algorithms, according to one or more machine learning models. In one embodiment, the feature detection component 30a may segment a set of 3D part geometry features (e.g., a set of polygons such as triangles which collectively define the 3D part) into subsets of the features, each subset corresponding to a detected feature. For example, one subset of polygons may collectively define a chamfer, while another subset of polygons may collectively define a bolt hole pattern. The 3D part geometry features may be defined within a design or 3D print file (e.g., CAD or STL file). In one embodiment, the file may contain information defining features of the 3D part, and the feature detection component 30a may process such information to detect features. In one embodiment, the feature detection component 30a is operable to detect one or both of primitive features (planes, spheres, cylinders, etc.) and abstract features (threaded holes, custom mounting brackets, etc.). In one embodiment, the feature detection component 30a may be implemented as one or more machine learning models, which may be trained using user data and feedback, as will be described in further detail below.

In one embodiment, the feature detection component 30a may employ random sample consensus (RANSAC) as an alternative or in addition to machine learning. For example, where a reference feature shape is defined using metadata, the feature detection component 30a may utilize RANSAC to search for that shape within the 3D part geometry. This approach may be used to find features of any arbitrary shape.

In one aspect of the invention, the feature classification component 30b operates to classify 3D part geometry features detected by the feature detection component 30a. In one embodiment, the feature classification component 30b may be implemented using one or more machine learning-based algorithms, according to one or more machine learning models, as will be described in further detail below.

In one embodiment, the feature classification component 30b may additionally or alternatively utilize metadata from a reference feature shape (e.g., input to a RANSAC search for the feature detection component 30a) to classify the corresponding detected feature.

The feature classification component 30b may classify features according to one or more hierarchies of features. For example, the feature classification component 30b may classify a feature as a cylinder, but may further classify the feature as an M6 bolt, and then may even further classify the feature as one of an array of M6 bolts. In this regard, the feature classification component 30b may perform multiple passes of classification (e.g., the first classification pass determines the feature to be a cylinder, the second classification pass further determines the feature to be an M6 bolt, etc.).

In one embodiment, the feature classification component 30b may receive classification information from information contained in a design or 3D print file (e.g., CAD or STL file).

In one embodiment, the feature classification component 30b may classify features as critical features and other features as non-critical features. In one embodiment, the feature classification component 30b may store, e.g., in a database, geometric description of input geometry, critical features, and non-critical features. The database of critical features may then be used to train one or more feature classification model(s) (e.g., machine learning model(s)) used by the feature classification component 30b for classification.

In one embodiment, the machine learning model(s) may be based on “semantic segmentation” of point clouds, as will be described in further detail below. In one embodiment, the machine learning model(s) may be trained using user/customer feedback, as will be described in further detail below. In one embodiment, the machine learning model(s) may be trained using user/customer data and feedback, as will be described in further detail below.

In one embodiment, the feature detection component 30a may maintain a machine learning model where training and/or use of the model is open to multiple users (or multiple categories of users). For instance, such a machine learning model may receive training data from all users who consent to use of their 3D part data for machine learning training purposes.

In one embodiment, the feature classification component 30b likewise maintains a machine learning model where training and/or use of the model is open to multiple users (or multiple categories of users). That is, the learning models employed may be of a “federated” type, where a machine learning model may use all user data for training.

In one embodiment, the feature detection component 30a maintains one or more machine learning model(s) where training and/or use of the model(s) are limited to only a single user (or a single category or subset of users) or a single or limited use case. For instance, a machine learning model may receive training data and/or feedback from a single user or corporation. Such restriction may be useful, for example, in the case of a security-conscious company for limiting use of its 3D part data while still retaining use of the feature analysis component 30. In one embodiment, the feature classification component 30b likewise maintains one or more machine learning model(s) where training and/or use of the model are limited to only a single user (or a single category of users) or a single or limited use case. That is, the learning model(s) employed may be built in a user-specific case, where specific users' (e.g., customers') data and/or feedback may be excluded from training a universal machine learning model but may be used to train one or more machine learning model(s) specific to that user. For example, an automotive manufacturer's machine learning model(s)s may be trained to detect only that manufacturer's cupholders and to identify various features as critical features, while separate (e.g., general) machine learning models, provided for other manufacturers, are not trained using this manufacturer's cupholders and not used to identify those cupholders as critical features

In one embodiment, one or both of the feature detection component 30a and the feature classification component 30b maintains multiple tiers of machine learning models. For example, one or more lower-tier (e.g., initial) machine learning models may be trained based on user data and/or feedback from all users/customers or at least a larger subset of users/customers. That is, the lower-tier machine learning model(s) may be used universally or globally for all users/customers. One or more higher-tier (e.g., refined) machine learning models may then be further trained using the lower-tier machine learning model(s) as a basis, further refined using additional user/customer data and/or feedback specific to a particular user/customer or a subset of users/customers.

In one embodiment, one or both of the feature detection component 30a and the feature classification component 30b maintain one or more databases to store the data for implementing the machine learning model(s). In one embodiment, the cloud computing platform 2000 implementing the feature analysis component 30 is administered by the manufacturer of the 3D printer, a third-party service, etc.

It will be appreciated that while the feature analysis component 30 is illustrated in FIG. 2 as being implemented as part of the cloud computing platform 2000, the feature analysis component 30 may alternatively be implemented on a local computing platform (e.g., in physical or network proximity to the 3D printing apparatus 1000) or may even be integrated with the 3D printing apparatus 1000. In one embodiment, the feature analysis component 30 may implemented by combining two or more of the aforementioned components (e.g., as a hybrid architecture combining both local and cloud computing).

Operation to Determine Critical Features

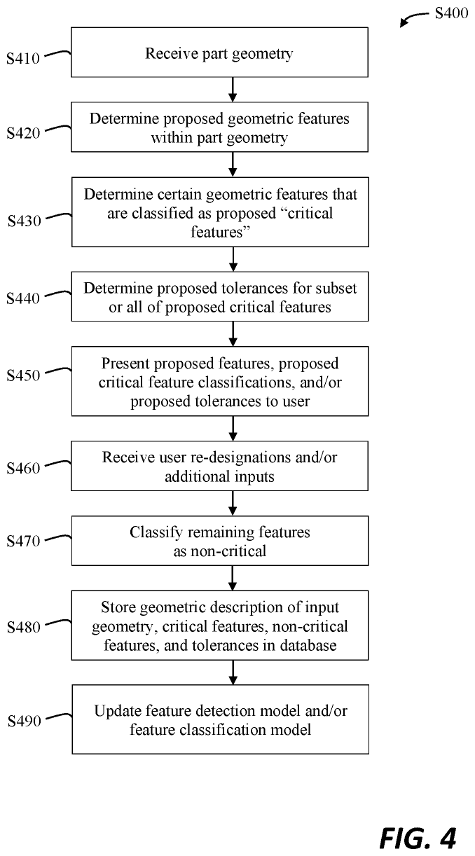

FIG. 4 illustrates an operation S400 to train the feature detection and feature classification machine learning models, according to one embodiment.

First, in step S410, the feature analysis component 30 receives part geometry of a 3D part to be printed. In one embodiment, the system 100 receives the part geometry over a network, such as an internal network or the Internet. In one embodiment, the feature analysis component 30 receives a 3D CAD or other design file. The feature analysis component 30 may receive the file from the 3D printing apparatus 1000 or the user computing device 3000.

In step S420, the feature detection component 30a determines, using a current feature detection model, proposed geometric features within the 3D part geometry.

In step S430, the feature classification component 30b determines, using one or more current feature classification models, classification of certain geometric features. In one embodiment, such classification includes the classification of certain geometric features as proposed “critical features.” These classified critical features may be determined to be of higher importance as to dimensional accuracy and/or strength relative to other features in the 3D part.

In one embodiment, the feature classification component 30b determines other classifications in addition to, or as an alternative to, critical features. It will be appreciated that a variety of other classifications may be determined including, but not limited to, shapes (e.g., cylinder, threaded hole, etc.), physical characteristic (e.g., flat, curved, etc.), purpose/function or intended use (e.g., fastener, bearing, etc.), or any other suitable form of classification. It will also be appreciated that the classifications, including for critical features and for other features, may include a numeric or ranking component. For example, the determined critical features may include a determination of the criticality (e.g., a percentage between 0 and 100%). Ultimately, a classification is a label that is applied to a particular feature or set of features.

In step S440, the feature classification component 30b determines, using the current feature classification model(s), proposed tolerances (e.g., dimensional) for the proposed critical features (or a subset or all of the proposed features). The tolerances for the classified critical features are deemed “critical tolerances.” It will be appreciated that the determination of proposed tolerances may extend to proposed features in general, and is not limited to critical features. For instance, bolt holes in a 3D part may not be designated critical, but the feature classification 30b may nonetheless determine specific proposed tolerances for these bolt holes.

In step S450, the feature analysis component 30 causes the presentation of the proposed features, proposed critical feature classifications and/or other classifications, and/or proposed tolerances to a user of the system 100. In one embodiment, the system 100 may present this information to a user via a user interface of the 3D printing apparatus 1000. In one embodiment, the system 100 may present this information to a user via a user interface (e.g., web or dedicated application interface) of the user computing device 3000. In one embodiment, the information may include highlighting (or otherwise distinguishing) the proposed geometric features and/or the proposed critical features in a visual representation of the 3D part geometry.

In step S460, the feature analysis component 30 receives:
(i) user re-designation of proposed features and/or input of additional features,
(ii) user re-designation of proposed critical feature classifications and/or other classifications, and/or input of additional critical feature and/or other classifications (e.g., customer input of additional critical features not previously classified), and/or
(iii) user re-designation of proposed tolerances and/or input of additional tolerances, such as any form of geometric dimensioning and tolerancing (GD&T) including, for example but not limited to, ASME Y14.5.

Such information may be received from the user via the same user interface utilized for presentation in step S450, or may be received via another means.

In step S470, based on the user re-designation and/or additional input, the feature analysis component 30 segregates the remaining identified features not identified as critical, and classifies these features as non-critical features.

In step S480, the feature analysis component 30 stores (e.g., in one or more databases maintained in connection with the feature analysis component 30) geometric description of input geometry, classifications (e.g., critical and non-critical, and/or other determined classifications), and tolerances.

In S490, the feature analysis component 30 updates (e.g., further trains) the feature detection model and/or the feature classification model, using the database(s) maintained in connection with the feature analysis component 30. Various examples of such a training procedure are described below. However, it will be appreciated that the invention is not limited to these particular exemplary training procedures, and that other procedures for updating the feature detection model and/or the feature classification model may be employed in connection with the invention.

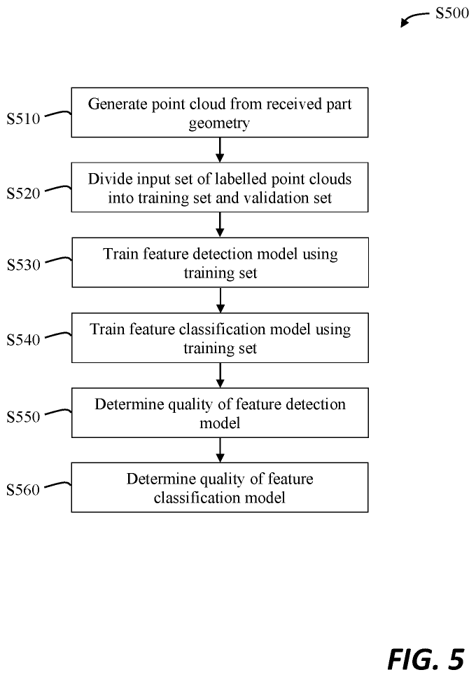

FIG. 5 illustrates an operation S500 to train the feature detection and feature classification models to detect geometric features within 3D part geometry using a semantic segmentation approach, according to one embodiment. Operation S500 may be used to perform step S490.

In step S510, the feature detection component 30a generates a point cloud from received 3D part geometry, where features have been labelled on a per-face or per-point basis with the desired classification for a respective feature. For example, in one embodiment, a point cloud may be generated via Poisson disk sampling, where the disk radius scales with feature size. In one embodiment, a point cloud may be generated via a uniform random distribution.

A point cloud generation approach overcomes a potential issue where large features are defined by only several points. The points may be labelled by association to the faces they project into. For example, point A may project onto face B which is part of feature C having been classified, so point A receives the classification of feature C.

In step S520, the feature detection component 30a splits the input set of labelled point clouds into (i) a training set and (ii) a validation set. In one embodiment, the split is performed by randomly sampling a certain percentage of the point clouds, assigning the sampled point clouds to the training set, and assigning the remaining point clouds to the validation set. In one embodiment, the split is performed by randomly sampling first and second percentages of the point clouds, assigning the first percentage-sampled point clouds to the training set, assigning the second percentage-sampled point clouds to a test set, and assigning the remaining point clouds to the validation set. In this regard, the test set may be used for an unbiased analysis of the final performance of the model. In one embodiment, the percentage of point clouds to be assigned to the training set is between 10-30%. In one embodiment, the percentage of point clouds to be assigned to the test set is between 10-30%.

In step S530, the feature detection component 30a trains the feature detection model(s) using the training set. That is, the feature detection model(s) is trained against pre-labelled point clouds in the training set. This training may be accomplished by a number of known machine learning approaches, such as via use of Open3D-ML. The training may involve adjusting model parameters so that the model accurately matches training data. This may be accomplished manually, or using an existing optimization algorithm such as (but not limited to) “gradient descent” “monte carlo,” “newtons method,” etc.

In step S540, the feature classification component 30b trains the feature classification model(s) using the training set. This training may be accomplished by a number of known machine learning approaches, such as those discussed herein.

In step S550, the feature analysis component 30 determines the quality of the feature detection model(s), by (i) exercising the model(s) to predict classifications of features in the validation set and (ii) comparing each predicted classification against the respective actual classification.

In step S560, the feature analysis component 30 determines the quality of the feature classification model, by (i) exercising the model to predict labels of the validation set and (ii) comparing each predicted label against the respective actual label.

Upon training, the models may be used to: (i) identify features in general, (ii) predict a classification of identified features as “critical” or “non-critical” (and/or other classifications), and/or (iii) predict an expected tolerance for the expected predicted critical and non-critical features.

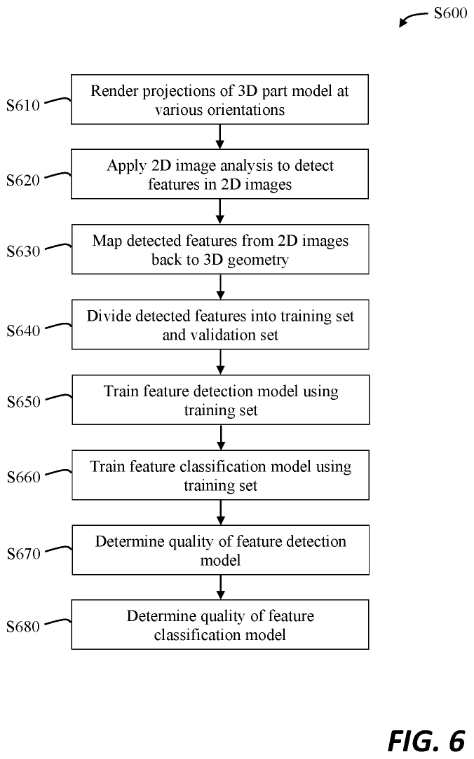

FIG. 6 illustrates an operation S600 for detecting geometric features within 3D part geometry using a forced projection approach, according to one embodiment. Operation S600 may be used to perform step S490.

In step S610, the feature detection component 30a renders projections of the 3D part model at various orientations to form 2D images according to the various orientations.

In step S620, the feature detection component 30a applies existing 2D image analysis techniques (e.g., using machine learning) to detect features in the 2D images. Examples of such 2D image analysis techniques that may be employed for use in this step may include, but are not limited to, RANSAC, scale-invariant feature transform (SIFT), speeded up robust features (SURF), gradient location and orientation histogram (GLOH), histogram of oriented gradients (HOG), and a deep learning model, including one that incorporates transfer learning.

In step S630, the feature detection component 30a maps the detected features from the 2D images back to the original 3D geometry of the 3D part model, thereby providing the identification of the detected features in the 3D geometry.

In step S640, the feature detection component 30a splits the input set of detected features into (i) a training set and (ii) a validation set.

In step S650, the feature detection component 30a trains the feature detection model(s) using the training set. That is, the feature detection model(s) is trained against the detected features in the training set.

In step S660, the feature classification component 30b trains the feature classification model(s) using the training set. This training may be accomplished by a number of known machine learning approaches, such as those discussed herein.

In step S670, the feature analysis component 30 determines the quality of the feature detection model(s), by (i) exercising the model(s) to predict classifications of features in the validation set and (ii) comparing each predicted classification against the respective actual classification.

In step S680, the feature analysis component 30 determines the quality of the feature classification model, by (i) exercising the model to predict labels of the validation set and (ii) comparing each predicted classification against the respective actual classification.

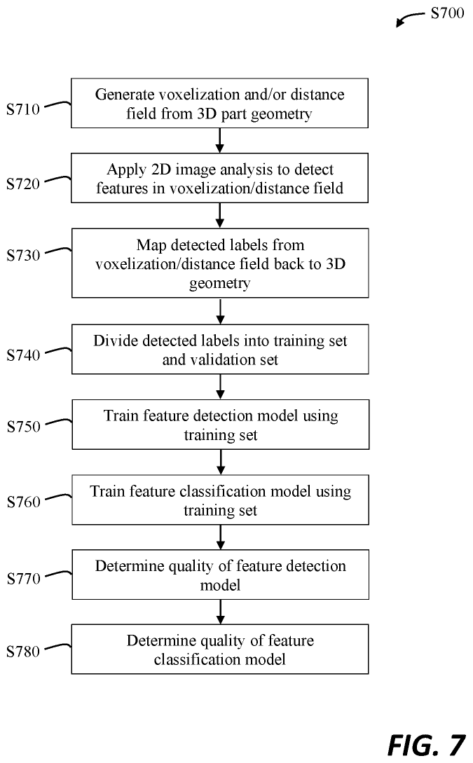

FIG. 7 illustrates an operation S700 for detecting geometric features within 3D part geometry using a voxelization approach, according to one embodiment. Operation S700 may be used to perform step S490.

In step S710, the feature detection component 30a generates a voxelization and/or distance field from the 3D part geometry.

In step S720, the feature detection component 30a applies existing 2D image analysis techniques (e.g., using machine learning) to detect features in the voxelization and/or distance field. An example of such 2D image analysis techniques that may be employed for use in this step may include, but is not limited to, the approach described in Bei Wang et al., Voxel-FPN: multi-scale voxel feature aggregation in 3D object detection from point clouds, arXiv, 2019, which is incorporated by reference herein in its entirety. Other examples of techniques include, but are not limited to, RANSAC or a voxel-based 3D detection and reconstruction approach such as that described in Feng Liu et al., Voxel-based 3D Detection and Reconstruction of Multiple Objects from a Single Image, Proceeding of Thirty-fifth Conference on Neural Information Processing Systems (NeurIPS 2021), Virtual, December 2021, which is incorporated by reference herein in its entirety.

In step S730, the feature detection component 30a map the detected features from the voxelization/distance field back to the original 3D geometry of the 3D part model, thereby providing the identification of the detected features in the 3D geometry.

In step S740, the feature detection component 30a splits the input set of detected features into (i) a training set and (ii) a validation set.

In step S750, the feature detection component 30a trains the feature detection model(s) using the training set. That is, the feature detection model(s) is trained against the detected features in the training set.

In step S760, the feature classification component 30b trains the feature classification model(s) using the training set. This training may be accomplished by a number of known machine learning approaches, such as those discussed herein.

In step S770, the feature analysis component 30 determines the quality of the feature detection model(s), by (i) exercising the model(s) to predict classifications of features in the validation set and (ii) comparing each predicted classification against the respective actual classification.

In step S780, the feature analysis component 30 determines the quality of the feature classification model, by (i) exercising the model to predict labels of the validation set and (ii) comparing each predicted classification against the respective actual classification.

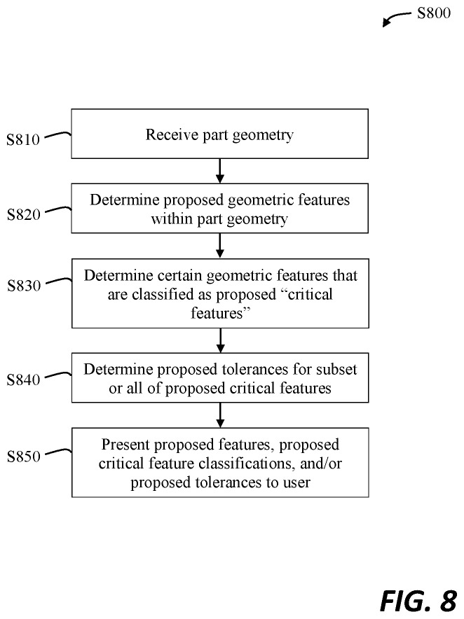

FIG. 8 illustrates an operation S800 for presenting critical features to a user in a 3D printing operation, according to one embodiment.

In step S810, the system 100 receives part geometry of a 3D part to be printed, similar to step S410 described above.

In step S820, the feature detection component 30a determines, using a current feature detection model, proposed geometric features within the 3D part geometry, similar to step S420 described above.

In step S830, the feature classification component 30b determines, using one or more current feature classification models, classification of certain geometric features, similar to step S430 described above.

In step S840, the feature classification component 30b determines, using the current feature classification model(s), proposed tolerances (e.g., dimensional) for the proposed critical features (or a subset or all of the proposed features), similar to step S440 described above.

In step S450, the feature analysis component 30 causes the presentation of the proposed features, proposed critical feature classifications and/or other classifications, and/or proposed tolerances to a user of the system 100, similar to step S450 described above.

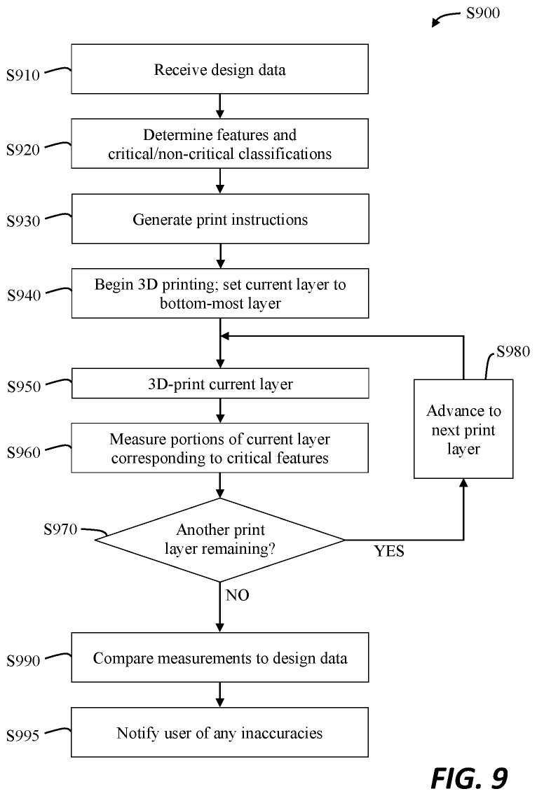

FIG. 9 illustrates an operation S900 for in-process detection of print accuracy of critical features, according to one embodiment.

In step S910, the feature analysis component 30 receives design data relating to an object to be 3D printed. The design data may be received in any number of different ways. For example, the design data may be received by the apparatus 1000 and then transmitted by the apparatus 1000 to the feature analysis component 30 via the network 25. Or the design data may be sent from the user computing device 3000 to the cloud computing platform 2000 via the network 25.

In step S920, the feature analysis component 30 determines features of the object based on the design data, based on one of the approaches described herein. The feature analysis component 30 also determines classifications (critical/noncritical and/or other classifications) of the determined features, based on one of the approaches described herein.

In step S930, the system 100 generates print instructions based on the design data. Such generation may be performed by the feature analysis component 30, by the apparatus 1000, by the user computing device 3000, or by another computing component. The print instructions are provided to the controller 20 of the apparatus 1000.

In step S940, the controller 20 initiates the 3D-printing operation of the object, setting the current layer to be printed as the bottom-most print layer.

In step S950, the controller 20 controls the motors 116, 118 with motor commands, and causes the print head(s) 10, 18 to print the current layer based on print head assembly movement commands and extruder commands for the current layer, as defined in the print instructions.

In step S960, the apparatus 1000 performs measurements on portions of the current layer corresponding to critical features. For example, the apparatus 1000 may include one or more sensors capable of performing dimensional (e.g., height) measurements of the current layer. Various aspects of such sensors and their operation are described in detail in U.S. Patent Application Publication No. 2020/0361155, which is incorporated by reference herein in its entirety.

In step S970, the controller 20 determines whether another print layer remains to be printed for the object. If another print layer remains to be printed, the operation proceeds to step S980. If the current print layer is the final print layer, the operation proceeds to step S990.

In step S980, the controller 20 increments the current print layer to the next layer, thereby advancing to the next layer. Generally, the next layer is the successive layer upwards in height. The operation then returns to step S950.

In step S990, the controller 20 compares the measurement data obtained in step S960 with expected data based on the geometry information in the design data, and identifies inaccuracies between the measurement data and expected data based on the comparison. This comparison identifies the defects in geometry within the actual printed object relative to the specified geometry of the object as defined by the design data. In one embodiment, the controller 20 applies surface modeling methodologies to the design data, to determine the expected distance for each measurement point. Various aspects of such measurement comparison are described in detail in U.S. Patent Application Publication No. 2020/0361155, which is incorporated by reference herein in its entirety.

In step S995, the controller 20 notifies the user of whether one or more inaccuracies in critical features were revealed based on the comparison performed in step S990. In one embodiment, the user is also notified as to which particular critical features were determined to be inaccurate based on the measurements.

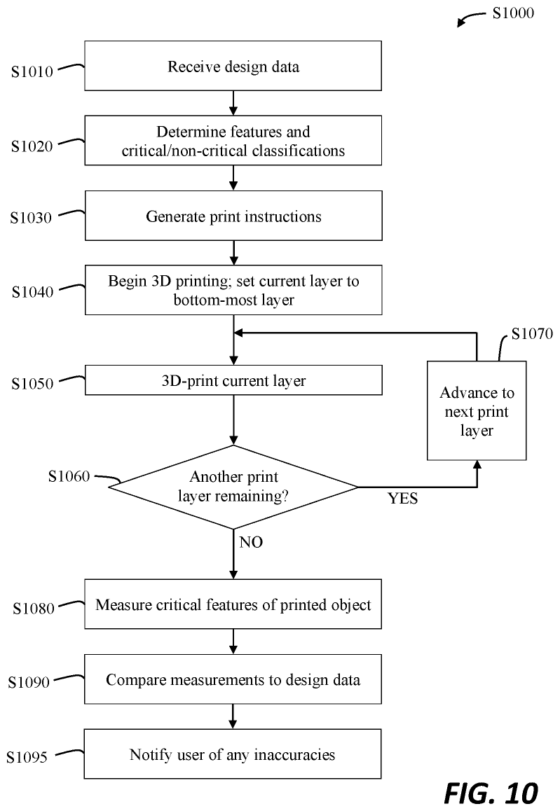

FIG. 10 illustrates an operation S1000 for post-process detection of print accuracy of critical features, according to one embodiment.

In step S1010, the feature analysis component 30 receives design data relating to an object to be 3D printed, similar to step S910.

In step S1020, the feature analysis component 30 determines features and also determines classifications (e.g., critical/non-critical and/or other classifications) of the determined features, similar to step S920.

In step S1030, the system 100 generates print instructions based on the design data, similar to step S930.

In step S1040, the controller 20 initiates the 3D-printing operation of the object, setting the current layer to be printed as the bottom-most print layer, similar to step S940.

In step S1050, the controller 20 controls the motors 116, 118 with motor commands, and causes the print head(s) 10, 18 to print the current layer based on print head assembly movement commands and extruder commands for the current layer, as defined in the print instructions, similar to step S950.

In step S1060, the controller 20 determines whether another print layer remains to be printed for the object, similar to step S970. If another print layer remains to be printed, the operation proceeds to step S1070. If the current print layer is the final print layer, the operation proceeds to step S1080.

In step S1070, the controller 20 increments the current print layer to the next layer, thereby advancing to the next layer, similar to step S980. Generally, the next layer is the successive layer upwards in height. The operation then returns to step S1050.

In step S1080, the controller 20 performs measurements of critical features of the 3D-printed object. For example, the apparatus 1000 may include one or more sensors capable of performing dimensional (e.g., height) measurements of the object. Various aspects of such sensors and their operation are described in detail in U.S. Patent Application Publication No. 2020/0361155, which is incorporated by reference herein in its entirety.

In step S1090, the controller 20 compares the measurement data obtained in step S1080 with expected data based on the geometry information in the design data, and identifies inaccuracies between the measurement data and expected data based on the comparison. This comparison identifies the defects in geometry within the actual printed object relative to the specified geometry of the object as defined by the design data. In one embodiment, the controller 20 applies surface modeling methodologies to the design data, to determine the expected distance for each measurement point. Various aspects of such measurement comparison are described in detail in U.S. Patent Application Publication No. 2020/0361155, which is incorporated by reference herein in its entirety.

In step S1095, the controller 20 notifies the user of whether one or more inaccuracies in critical features were revealed based on the comparison performed in step S1090. In one embodiment, the user is also notified as to which particular critical features were determined to be inaccurate based on the measurements.

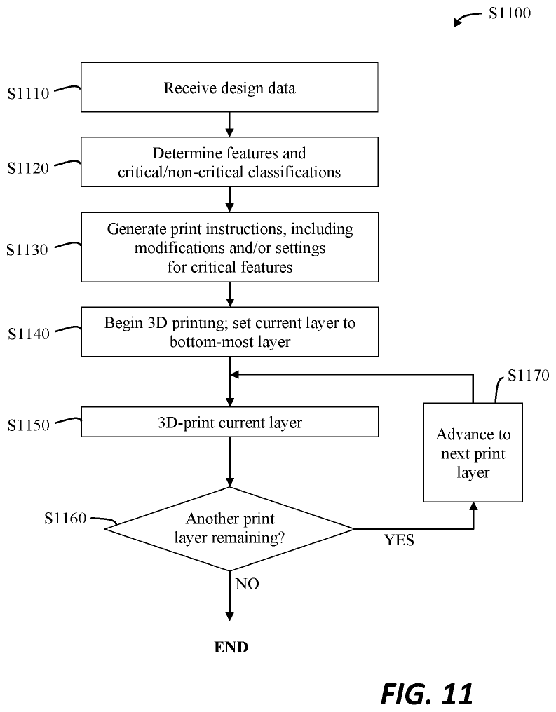

FIG. 11 illustrates an operation S1100 for compensation for critical features, according to one embodiment.

In step S1110, the feature analysis component 30 receives design data relating to an object to be 3D printed, similar to step S910.

In step S1120, the feature analysis component 30 determines features and also determines classifications (e.g., critical/non-critical and/or other classifications) of the determined features, similar to step S920.

In step S1130, the system 100 generates print instructions, including modified print instructions and/or settings for critical features (e.g., setting that improves strength of critical feature), based on the design data and the determined features and classifications in step S1120. For example, the modified print instructions/settings may include adjustment of a print setting that improves the strength of a critical feature. As another example, the modified print instructions/settings may include adjustment of a slicing setting that improves the strength of a critical feature. For example, the strength may be improved by including continuous carbon fiber, increasing fill density, increasing number of shells, etc.

In step S1140, the controller 20 initiates the 3D-printing operation of the object, setting the current layer to be printed as the bottom-most print layer, similar to step S940.

In step S1150, the controller 20 controls the motors 116, 118 with motor commands, and causes the print head(s) 10, 18 to print the current layer based on print head assembly movement commands and extruder commands for the current layer, as defined in the modified print instructions.

In step S1160, the controller 20 determines whether another print layer remains to be printed for the object, similar to step S970. If another print layer remains to be printed, the operation proceeds to step S1170. If the current print layer is the final print layer, the operation is concluded.

In step S1170, the controller 20 increments the current print layer to the next layer, thereby advancing to the next layer, similar to step S980. Generally, the next layer is the successive layer upwards in height. The operation then returns to step S1150.

It will be recognized that the operation S1100 to compensate for critical features (and/or other classifications) has numerous applications and benefits. As a first example, a 3D part may contain threaded holes that are printed without additional support by default, but if identified as a critical feature, may be printed with support. As a second example, a 3D part may contain mounting brackets of a known shape may be classified as a critical feature with known strength requirements, and the print instructions may be modified in step S1130 for continuous fiber or solid infill in that mounting bracket region. As a third example, a 3D part may contain features classified as “requires machining,” such that these features are printed with extra sacrificial shells that enable machining of the part surface. As a fourth example, a 3D part may contain features classified as “conformal cooling channels,” such that these features are automatically filled with supports to form a contiguous pore so that fluid can freely flow therethrough, but the overall channel geometry (which requires support) is still successfully printed.

It will be appreciated that additional user interface features are within the scope of the invention. For example, the user interface for a user may include tools allowing users to instruct the feature analysis component 30 on more appropriate feature labelling such as (but not limited to):
(1) Features may be labelled by the user using a predefined label (e.g., plane), or the user may create his/her own label to add to an existing list of labels.
(2) Users may select multiple object faces and select the appropriate label.
(3) Users may select an appropriate label, and one or more faces known to share that label. The feature analysis component 30 may then utilize this information to assist inference of remaining faces that should receive that label.
(4) Users may select multiple primitive features and combine them to form a new feature for them to label.
(5) Users may select a specific feature label and use a “find more” or “suggest” tool which applies the RANSAC algorithm to identify parts of the geometry that fit the typical shape of features with this label.
(6) Some combinations of all the foregoing approaches.

Additional/alternative uses based on identifying critical features may include, but are not limited to:
(1) The system may suggest to a user that critical features that are known to not print/perform well with one process (e.g., composite), instead be printed with another process (e.g., metal).
(2) The system may highlight sections of a part that are known not to conform to recommendations for “design for additive manufacturing.”
(3) The system may provide more efficient critical dimensioning.
(4) To enhance privacy, the system may train against models for specific users without storing identifiable information.

The approaches described above may rely on customer input to train the machine learning models. This is often referred to as “supervised” learning. However, additional/alternative approaches to training machine learning models that may be used within the scope of the invention may include, but not are limited to:
(1) Unsupervised approaches—The system may incorporate “unsupervised” learning by constructing a system that generates training data (e.g., pre-labeled CAD geometry). For example, a CAD system may recognize the label of any geometry created (i.e., whether it is cylindrical, threaded, part of a pattern, etc.), and these feature labels may be included in any exported data from the CAD system. The training data may therefore be randomly generated within a CAD system and exported with classification labels.
(2) CAD Integration— The system may utilize feature labels from a CAD system as above, but rather than randomly generating the geometry, may use data from actual user-generated CAD models.
(3) Human-labeled Data—A user may be engaged to label 3D print data for criticality and other classifications.

### Other Embodiments

Incorporation by reference is hereby made to U.S. Pat. Nos. 10,076,876, 9,149,988, 9,579,851, 9,694,544, 9,370,896, 9,539,762, 9,186,846, 10,000,011, 10,464,131, 9,186,848, 9,688,028, 9,815,268, 10,800,108, 10,814,558, 10,828,698, 10,953,609, U.S. Patent Application Publication No. 2016/0107379, U.S. Patent Application Publication No. 2019/0009472, U.S. Patent Application Publication No. 2020/0114422, U.S. Patent Application Publication No. 2020/0361155, U.S. Patent Application Publication No. 2020/0371509, and U.S. Provisional Patent Application No. 63/138,987 in their entireties.

Although this invention has been described with respect to certain specific exemplary embodiments, many additional modifications and variations will be apparent to those skilled in the art in light of this disclosure. For instance, while reference has been made to an X-Y Cartesian coordinate system, it will be appreciated that the aspects of the invention may be applicable to other coordinate system types (e.g., radial). It is, therefore, to be understood that this invention may be practiced otherwise than as specifically described. Thus, the exemplary embodiments of the invention should be considered in all respects to be illustrative and not restrictive, and the scope of the invention to be determined by any claims supportable by this application and the equivalents thereof, rather than by the foregoing description.

What is claimed is:

1. An apparatus comprising:
at least one processor; and
at least one memory,
wherein the at least one memory stores computer-readable instructions which, when executed by the at least one processor, cause the processor to:
receive design data corresponding to an object;
determine, based on the design data, features of the object;
determine, of the determined features, at least one classification for at least one determined feature; and
generate production data based on the design data, the determined features, and the determined at least one classification.

2. The apparatus of claim 1, wherein the features of the object are determined using a machine learning model.

3. The apparatus of claim 1, wherein the at least one classification includes a classification that a feature is a critical feature.

4. The apparatus of claim 3, wherein features are determined to be classified as critical features using a machine learning model.

5. The apparatus of claim 3, wherein the computer-readable instructions which, when executed by the at least one processor, cause the processor to:
determine, for at least one of the features classified as a critical feature, a tolerance threshold for dimensional accuracy of the critical feature when the object is produced.

6. The apparatus of claim 5, wherein the determined tolerance threshold is different from a tolerance threshold for another determined feature of the object when the object is produced.

7. The apparatus of claim 1, wherein the design data is design data corresponding to an object to be 3D printed, and
wherein the production data is 3D print data.

8. The apparatus of claim 1, wherein the computer-readable instructions which, when executed by the at least one processor, cause the processor to:
receive, from a user, information corresponding to (i) a re-designation of a determined feature, (ii) a re-designation of a determined classification, (iii) an additional feature of the object beyond the features determined by the processor, or (iv) an additional classification for a feature beyond the at least one classification determined by the processor.

9. The apparatus of claim 3, wherein the generating of production data includes adjusting a production parameter based on the at least one classification that a determined feature is a critical feature.

10. An apparatus comprising:
at least one processor; and
at least one memory,
wherein the at least one memory stores computer-readable instructions which, when executed by the at least one processor, cause the processor to:
generate a machine learning model configured to recognize features in a design of an object;
receive design data corresponding to an object;
execute the machine learning model on the design, to output recognized features in the design;
present the recognized features to a user;
receive feedback relating to the recognized features; and
update the machine learning model, based on the feedback relating to the recognized features.

11. The apparatus of claim 10, wherein the machine learning model is a first machine learning model, and
wherein the computer-readable instructions which, when executed by the at least one processor, cause the processor to:
generate a second machine learning model configured to classify recognized features in the design;
execute the second machine learning model on the recognized features, to output one or more classifications corresponding to one or more recognized features;
present the classifications to a user;
receive feedback relating to the classifications; and
update the second machine learning model, based on the feedback relating to the classifications.

12. The apparatus of claim 11, wherein one or more of the one or more classifications is a classification that a feature is a critical feature.

13. A method comprising:
receiving design data corresponding to an object;
determining, based on the design data, features of the object;
determining, of the determined features, at least one classification for at least one determined feature; and
generating production data based on the design data, the determined features, and the determined at least one classification.

14. The method of claim 13, wherein the determining of the features of the object includes using a machine learning model to determine the features of the object.

15. The method of claim 13, wherein the at least one classification includes a classification that a feature is a critical feature.

16. The method of claim 15, wherein the determining of the features to be classified as critical features includes using a machine learning model to determine the features to be classified as critical features.

17. The method of claim 15, further comprising determining, for at least one of the features classified as a critical feature, a tolerance threshold for dimensional accuracy of the critical feature when the object is produced.

18. The method of claim 17, wherein the determined tolerance threshold is different from a tolerance threshold for another determined feature of the object when the object is produced.

19. The method of claim 13, wherein the design data is design data corresponding to an object to be 3D printed, and
wherein the production data is 3D print data.

20. The method of claim 13, further comprising receiving, from a user, information corresponding to (i) a re-designation of a determined feature, (ii) a re-designation of a determined classification, (iii) an additional feature of the object beyond the features determined by the processor, or (iv) an additional classification for a feature beyond the at least one determined classification.

21. The method of claim 15, wherein the generating of production data includes adjusting a production parameter based on the at least one classification that a determined feature is a critical feature.

22. A method comprising:
generating a machine learning model configured to recognize features in a design of an object;
receiving design data corresponding to an object;
executing the machine learning model on the design, to output recognized features in the design;
presenting the recognized features to a user;
receiving feedback relating to the recognized features; and
updating the machine learning model, based on the feedback relating to the recognized features.

23. The method of claim 22, wherein the machine learning model is a first machine learning model, and
wherein the method further comprises:
generating a second machine learning model configured to classify recognized features in the design;
executing the second machine learning model on the recognized features, to output one or more classifications corresponding to one or more recognized features;
presenting the classifications to a user;
receiving feedback relating to the classifications; and
updating the second machine learning model, based on the feedback relating to the classifications.

24. The method of claim 23, wherein one or more of the one or more classifications is a classification that a feature is a critical feature.
